(19) United States
(12) Patent Application Publication
(10) Pub. No.: US 2025/0392297 A1
(43) Pub. Date: Dec. 25, 2025

(54) DUTY CYCLE CORRECTION FOR HIGH-SPEED RECEIVER

(71) Applicant: Micron Technology, Inc., Boise, ID (US)

(72) Inventor: Vivek Venkata Kalluru, San Jose, CA (US)

(73) Assignee: Micron Technology, Inc., Boise, ID (US)

(21) Appl. No.: 19/242,800

(22) Filed: Jun. 18, 2025

Related U.S. Application Data
(60) Provisional application No. 63/663,012, filed on Jun. 21, 2024.

(51) Int. Cl. H03K 5/156; H04B 1/40

(52) U.S. Cl. CPC H03K 5/1565; H04B 1/40

(57) ABSTRACT

Methods, systems, and devices for techniques for duty cycle correction are described. The duty cycle correction can be performed for an input receiver of an input/output (I/O) circuit operable to communicate data. The input receiver comprises an analog frontend operable in a multi-giga Hertz frequency range. The analog frontend comprises an input circuit stage configured to receive analog differential input signals from external of the I/O circuit; an output circuit stage configured to provide frontend differential output signals based on the received analog differential input signals; and a biasing circuit controllable to adjust common mode voltages of the frontend differential output signals such that duty cycles of the frontend differential output signals are varied.

### CROSS-REFERENCE TO RELATED APPLICATION

This application claims priority to U.S. Provisional Application No. 63/663,012, filed on Jun. 21, 2024, entitled “DUTY CYCLE CORRECTION FOR HIGH-SPEED RECEIVER,” the content of which is incorporated by reference in its entirety for all purposes.

### TECHNICAL FIELD

This disclosure relates to one or more systems for memory, including techniques for duty cycle correction in an input receiver used in high-speed data communication operations.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2B are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIG. 4 illustrates a prior art circuit for duty cycle correction in accordance with examples as disclosed herein.

FIG. 5 illustrates an example input receiver including a biasing circuit controllable to adjust common mode voltages for duty cycle correction, in accordance with examples as disclosed herein.

FIG. 6 illustrates waveforms of frontend differential output signals before and after duty cycle correction, in accordance with examples as disclosed herein.

FIG. 7 illustrates flowcharts showing a method that supports techniques for duty cycle correction in accordance with examples as disclosed herein.

### DETAILED DESCRIPTION

A memory device frequently includes input/output (I/O) circuits for receiving and/or transmitting data at a high speed such as in the multiple Giga Hertz frequency range. For example, data may be communicated between a memory device and a host system at 3.6 gigatransfers per second (GTs) or more. Transferring data at such a high speed imposes a higher requirement on the input receiver of the I/O circuits. An input receiver typically includes an analog frontend for receiving high-speed analog differential signals that represent the high-speed data. The input receiver may also amplify the received analog differential signals, filter them, perform duty cycle corrections, and/or perform other processing of the signals. The input receiver then provides output differential signals or a single-ended output signal for downstream processing such as digitizing, clock recovering, etc.

Existing input receivers may be bandwidth limited due to duty-cycle distortion of the high-speed analog differential signals. For example, when the analog frontend receives and amplifies the high-speed analog differential signals, it may introduce duty cycle distortions at the output of the analog frontend. The duty cycle distortions may, for example, increase or decrease the duty cycle of the frontend differential output signals from its desired value (e.g., 50%). The duty cycle distortions may thus cause the voltages and/or the timing of the frontend differential output signals to deviate significantly from their nominal values, which in turn reduces the eye openings of the frontend differential output signals. An eye opening typically refers to the space between the rising and falling edges of a signal in a graphical representation. A wide and well-defined eye opening indicates that the signal has good integrity, with clear distinctions between different signal levels. A good eye opening may also correspond to a reduced level of intersymbol interference (ISI). ISI occurs when signals transmitted over a communication channel interfere with one another. ISI can also cause distortion of signals, and thus limit the bandwidth of the signal communication.

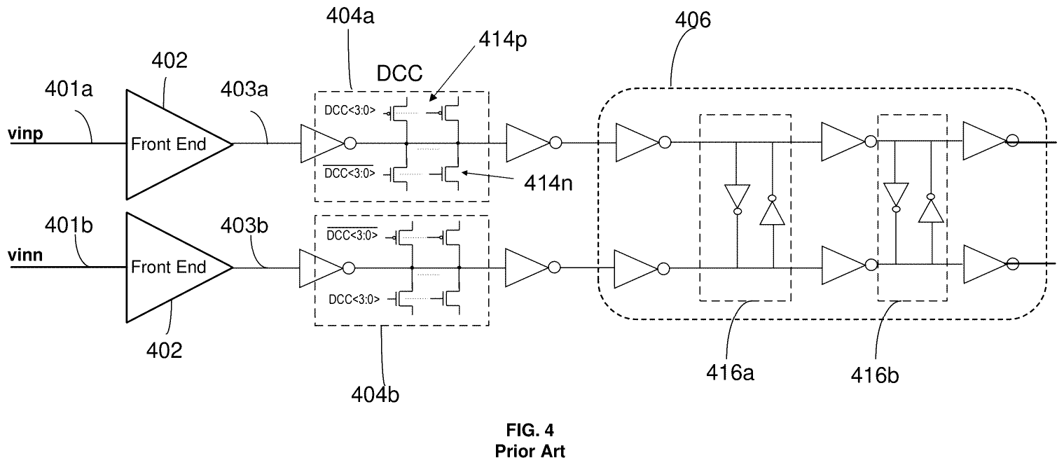

Technologies and circuits for duty cycle correction (DCC) have been developed. These existing DCC circuits are typically separate circuits from the analog frontend and are coupled to the output of the analog frontend. In one example, the DCC circuit is configured to have multiple pull-up and pull-down branches or legs, which are controlled independently to adjust the pull-up and/or pull-down speed of the analog frontend output differential signals. By adjusting the pull-up and/or pull-down speed, the voltage levels and/or the timing positions of rising edge and/or falling edge of the analog frontend output differential signals can be changed, thereby correcting the duty cycle. In some examples, additional blender circuits may also be used to improve the DCC correction performance. One example of the existing DCC circuits is shown in FIG. 4 and described in more detail below. However, because the existing DCC circuits are often separate circuits added to the output of the analog frontend, these existing DCC circuits increase the load at the output of the analog frontend. Increasing of the load likely decreases the speed of the analog frontend and limits the operational bandwidth. Furthermore, the increasing of the load of the analog frontend also increases the ISI, and thus reduces the eye opening of the frontend differential output signals (e.g., signals cannot swing from rail-to-rail because of the heavy load). Even worse, existing DCC circuits may also add significant more power consumptions.

Techniques and circuits described herein provide an input receiver using an analog frontend that has integrated DCC capabilities. The analog frontend disclosed herein includes a biasing circuit that is controllable to adjust common mode voltages of the frontend differential output signals such that the duty cycles of the frontend differential output signals are corrected or compensated, without using additional circuits that are added to the output of the analog frontend and thus without increasing the load of the analog frontend. The frontend differential output signals can thus have better eye openings, thereby improving the signal quality and integrity at the multi-giga Hertz transfer operation range. The common-mode based DCC circuits and techniques disclosed herein can therefore enable the input receiver to have a higher bandwidth and higher transfer speed without, or without substantially, increasing the layout area and power consumption of the input receiver. The techniques and circuits are further described in greater detail below.

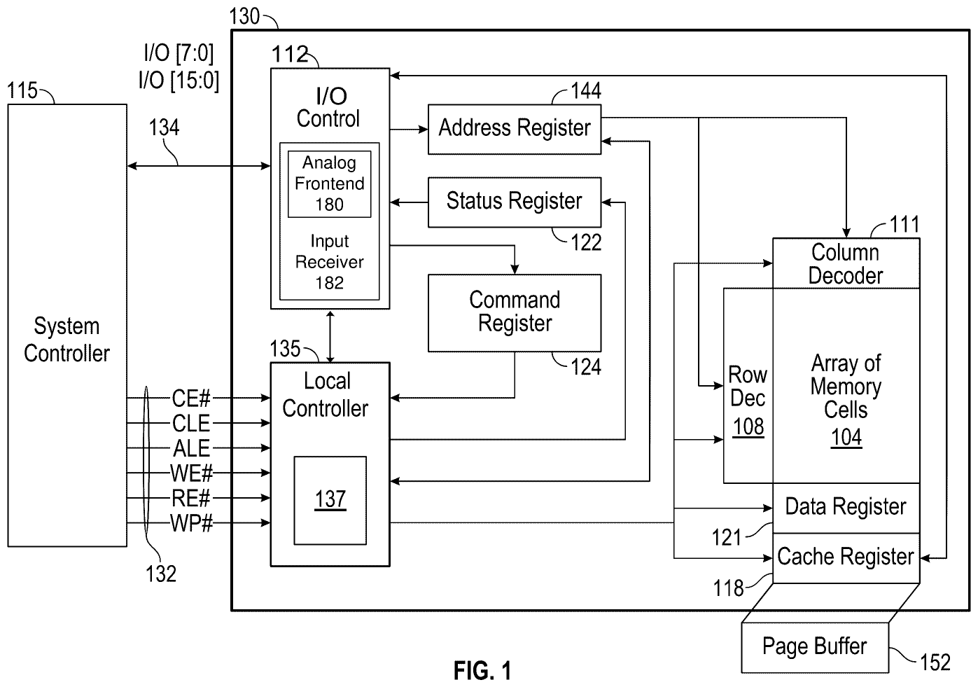

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. In some examples, I/O control circuitry 112 is also referred to as an I/O circuit, which includes an input receiver 182. An input receiver 182 can receives high-speed differential input signals, and generates output signals which may be digital signals for downstream processing. Input receiver 182 may include an analog frontend 180. The analog frontend 180 may include an integrated biasing circuit for performing duty cycle corrections, as described below in more detail. Memory device 130 may also include one or more registers. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

Memory device 130 further includes a memory controller. A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of memory device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local controller 135 to latch the status information for output to system controller 115.

As shown in FIG. 1, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

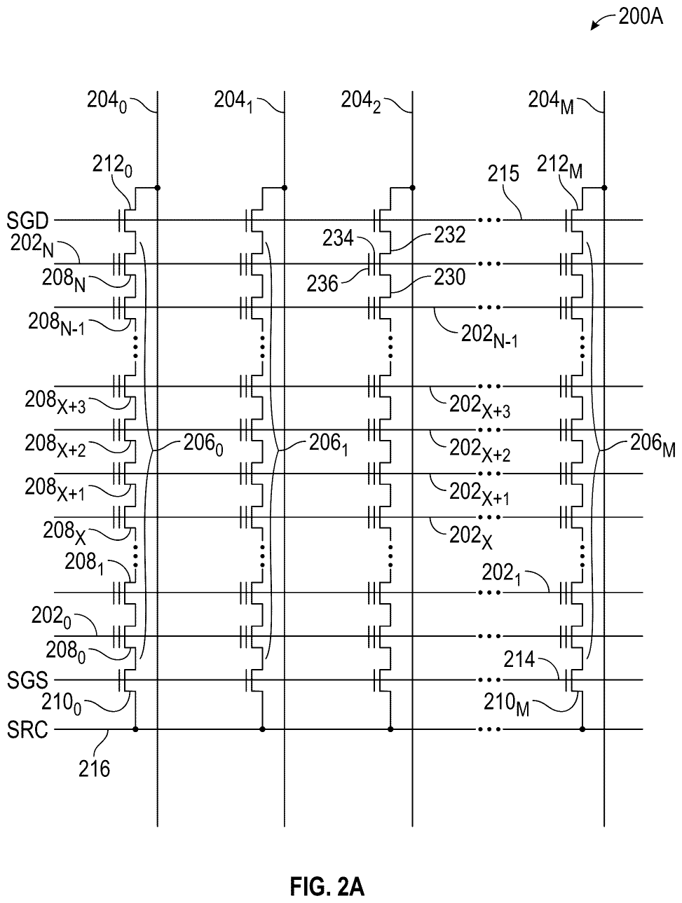

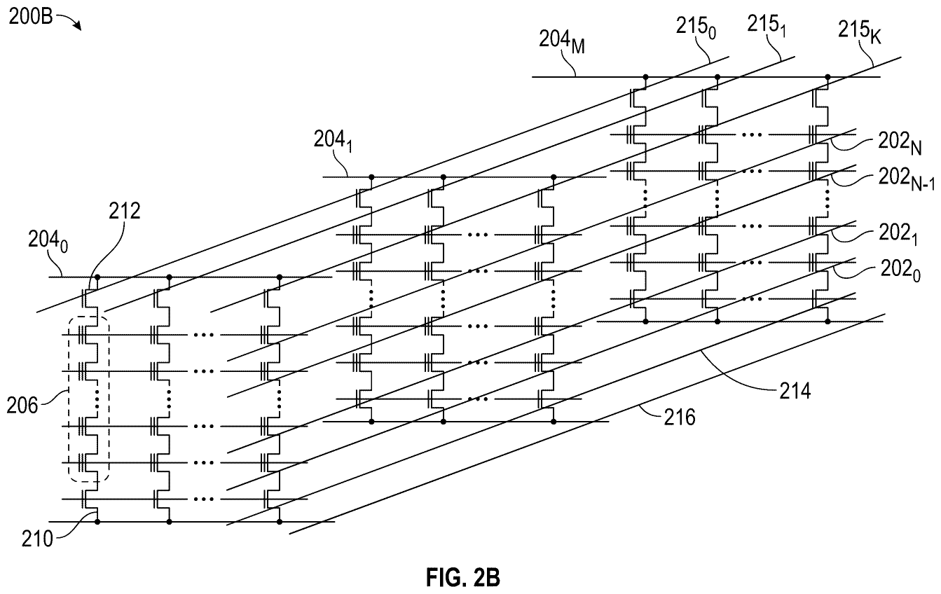

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

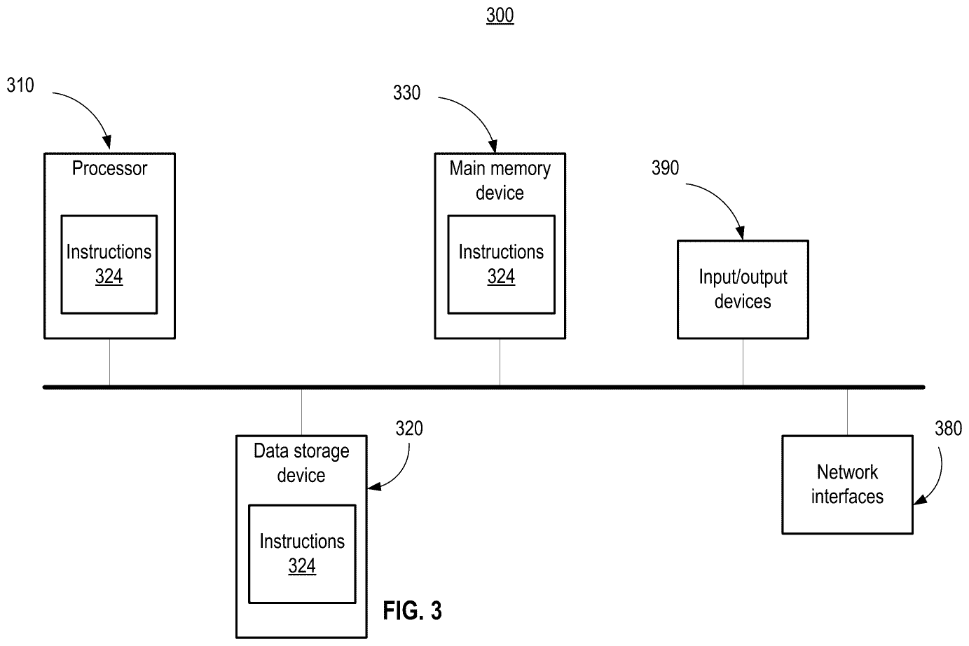

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-7, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-7 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-7. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

FIG. 4 illustrates a prior art circuit for duty cycle correction in accordance with examples as disclosed herein. With reference to FIG. 4, analog frontend 402 receives analog differential input signals 401a and 401b (collectively as differential input signals 401) from external of analog frontend 402. Based on the differential input signals 401, analog frontend 402 generates frontend differential output signals 403a and 403b (collectively as output signals 403). As described above, analog frontend 402 may cause duty cycle distortions in the process of receiving and processing the analog differential input signals 401. For example, when the analog frontend 402 receives and amplifies the differential input signals 401, it may introduce duty cycle distortions at its output. The duty cycle distortions may, for example, increase or decrease the duty cycle of the frontend differential output signals 403 from its desired value (e.g., 50%). The duty cycle distortions may thus cause the voltages and/or the timing of the frontend differential output signals 403 to deviate significantly from their nominal values, which in turn reduces the eye openings of the frontend differential output signals 403. As described above, a reduced eye opening typically limits the bandwidth of the I/O circuit, because the data communication error rate increases with a reduced eye opening.

FIG. 4 further illustrates existing duty cycle correction (DCC) circuits in an attempt to mitigate the duty cycle distortion induced by analog frontend 402. The circuits shown in FIG. 4 include DCC circuits 404a and 404b, and optionally blender circuit 406. They may also be a part of an input receiver used in an I/O circuit of a memory device. The DCC circuits 404 and blender circuits 406 shown in FIG. 4 are typically separate or additional circuits added to the output of the analog frontend 402. Thus, DCC circuits 404a and 404b receive the frontend differential output signals 403. In one example, the DCC circuit 404a is configured to have multiple pull-up branches 414p and multiple pull-down branches 414n. As shown in FIG. 4, the differential output signal 403a is coupled to both the multiple pull-up branches 414p and pull-down branches 414n. Similarly, differential output signal 403b is coupled to its associated pull-up branches and pull-down branches. Each of the multiple pull-up branches 414p includes one or more P-type transistors (e.g., PMOS); and each of the multiple pull-down branches 414n include one or more N-type transistors (e.g., NMOS). The one or more P-type transistors may be connected in serial; and the one or more N-type transistors may be connected in serial. Each of the pull-up branches is connected to the corresponding pull-down branches as shown in FIG. 4. DCC circuit 404a is for correcting the duty cycle of output signal 403a. DCC circuit 404b is configured like DCC circuit 404a but having opposite control signals. The following descriptions uses DCC circuit 404a as an example, but DCC circuit 404b operates similarly.

When DCC circuit 404a operates, the pull-up branches 414p receives input control signals DCC<3:0> to adjust the pull-up strength of the DCC circuit 404a. On the pull-down side, the pull-down branches 414n receives complimentary control signals D̅C̅C̅ <3:0> to adjust the pull-down strength of the DCC circuit 404a correspondingly. For example, if the duty cycle of the frontend differential output signal 403 is to be increased, the pull-up strength of DCC circuit 404a may be enhanced while its pull-down strength may be reduced or weakened. Accordingly, more transistors in the pull-up branches 414p may be turned on based on the control signal DCC <3:0> while more transistors in the pull-down branches 414n may be turned off based on the complimentary control signal D̅C̅C̅ <3:0>. If the duty cycle of the frontend differential output signal 403a is to be decreased, the pull-up strength of DCC circuit 404a may be weakened while its pull-down strength may be enhanced.

By adjusting the pull-up and/or pull-down strength of the DCC circuit 404a, the voltage levels and/or the timing positions of rising edge and/or falling edge of the frontend differential output signal 403a may be changed, thereby correcting its duty cycle (e.g., increasing the duty cycle or decreasing the duty cycle to be approximately 50%). One drawback of the DCC circuits 404a and 404b (collectively as 404) is that the load (e.g., capacitive and/or resistive impedance) of frontend differential output signals 403 is increased. The load at the output of the analog frontend 402 is increased because of the multiple pull-up and pull-down branches added to the output of analog frontend 402. The increased load slows down the rising and falling of signals 403, thereby reducing the operational speed of the analog frontend 402 (and in turn the input receiver or the I/O circuit). If the load becomes too large, the output signals 403 may even not be able to swing rail-to-rail (e.g., the signal voltage may not be able to rise all the way to the power supply before it starts to fall, or may not be able to fall all the way to the electrical ground before it starts to rise again). In some situations, the increased load may actually introduce more signal distortion and further reduce the eye opening. The reduction of the eye opening, and therefore bandwidth, may become worse when there is ISI.

In some examples, circuits shown in FIG. 4 may include additional blender circuits 406 to improve the DCC correction performance. As shown in FIG. 4, the blender circuit 406 includes one or more cross-coupled inverters circuit 416 (two such circuits 416a and 416b are shown). Using the cross-coupled inverters circuit 416a as an example, they are configured such that the output of one inverter is coupled to the input of the other inverter, and vice versa. The cross-coupled inverters in circuit 416a are disposed between the two frontend differential output signals 403a and 403b (or their buffered versions). The cross-coupled inverters form a positive feedback loop between the differential output signals 403a and 403b (or their buffered versions). Differential signals have opposite polarities (e.g., one negative and one positive relative to a common mode voltage, or a high state or a low state). The cross-coupled inverters therefore create a bistable state, improving the stability of the differential output signals 403a and 403b (or their buffered versions) such that they maintain their polarities (e.g., high or low) due to the feedback loop. In addition, the cross-coupled inverters can also boost the amplification gain of the analog frontend 402 at high frequencies. While the blender circuit 406 may provide some duty cycle correction performance enhancement, it further increases the load at the frontend differential output signals 403, thereby limiting the bandwidth of the input receiver and/or the I/O circuit. In addition, DCC circuit 404 and blender circuit 406 may significantly increase the power consumption of the input receiver and/or the I/O circuit.

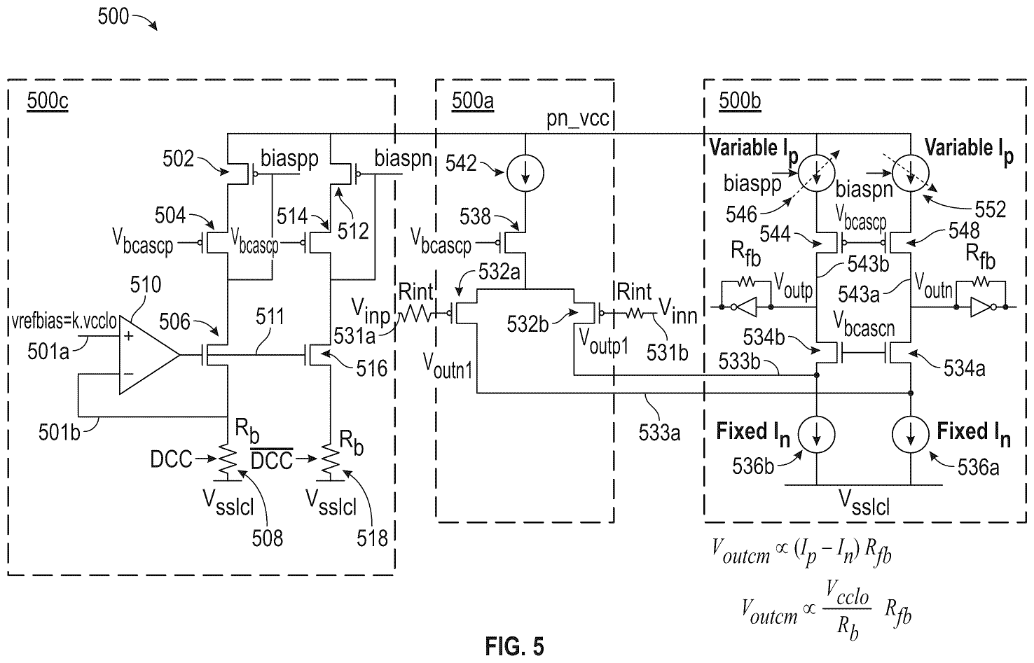

FIG. 5 illustrates an example analog frontend 500 including an integrated biasing circuit controllable to adjust common mode voltage of the differential output signals for duty cycle correction, in accordance with examples as disclosed herein. By adjusting the common mode voltage of the differential output signals, the duty cycle can be naturally corrected without having to use additional DCC correction circuits and thus without increasing the load at the output of the analog frontend. With reference to FIG. 5, analog frontend 500 may be used to implement analog frontend 180 of an input receiver 182 shown in FIG. 1. As shown in FIG. 1 and described above, the input receiver 182 may be a part of I/O control circuit 112, or I/O circuitry of another part of memory device 130.

With reference back to FIG. 5, in some embodiments, analog frontend 500 includes an input circuit stage 500a, an output circuit stage 500b, and a biasing circuit 500c. Input circuit stage 500a is configured to receive analog differential input signals 531a and 531b (collectively as 531) from external of the analog frontend 500, the input receiver (e.g., input receiver 182), the I/O circuitry (e.g., I/O control circuity 112), or a memory device (e.g., memory device 130). For example, the analog differential input signals 531 may be a part of data signals communicated using bus 134 sent by a system controller (e.g., controller 115) or host. The input circuit stage 500a of analog frontend 500 processes the analog differential input signals 531 and generates differential internal signals 533a and 533b, which are passed to the output circuit stage 500b. The output circuit stage 500b then generates the frontend differential output signals 543a and 543b. The differential input signals 531, internal differential signals 533, and differential output signals 543 are all analog signals. An analog signal represents information as continuously varying voltage, current, or other physical quantities, while a digital signal uses discreate values to represent data.

In some examples, analog frontend 500 includes a biasing circuit 500c for providing biasing voltage and/or biasing current to the input circuit stage 500a and output circuit stage 500b of analog frontend 500 for setting the operational points. In addition, biasing circuit 500c can be controlled to adjust common mode voltages of the differential output signals 543 and is described in more detail below. In one embodiments, based on the input circuit stage 500a, output circuit stage 500b, and biasing circuit 500c, analog frontend 500 amplifies the analog differential input signals 531, and generates frontend differential output signals 543, which are amplified analog differential signals. Frontend differential output signals 543 are then provided to downstream circuits such as cascaded inverter-based stages for further amplification and bandwidth extension. One such inverter-based stage is shown in FIG. 5. The example inverter-based stage includes two inverters connected to the respective output nodes of the output circuit stage 500b to receive respective differential output signals 543a and 543b. Each inverter also has its input and output connected to a feedback resistor R_{fb}. While FIG. 5 shows only one such inverter-based stage connected to each output node of output circuit stage 500b, it is understood that multiple such inverter-based stages can be cascaded together and coupled to the output nodes of the output circuit stage 500b. Cascaded inverter-based stages can provide continuous-time linear equalization (CTLE) for an input receiver (e.g., receiver 182 shown in FIG. 1) that incorporates the analog frontend 500. CTLE can be used to further mitigate the effects of signal distortion and to compensate for the frequency-dependent attenuation and phase distortion of the signals, thereby allowing the input receiver to recover the original transmitted signals more accurately. In some examples, cascaded inverter-based stages can output equalized differential signals to other circuitry of a memory device (e.g., device 130) or to another device, for further processing (e.g., digitizing, filtering, storing, or other processes). The input circuit stage 500a, output circuit stage 500b, and biasing circuit 500c of analog frontend 500 are described in greater detail below.

With reference still to FIG. 5, in some embodiments, analog frontend 500 includes a folded cascode circuit having an input transistor pair 532a-532b (collectively input transistor pair 532), cascode transistors 534a-534b (collectively cascode transistors 534), and biasing and/or current source transistors (e.g., 536a-536b, 538, 542, 544, 546, 548, and 552). The input transistor pair 532 is located in the input circuit stage 500a to receive the analog differential input signals 531; and the cascode transistors 534 are located in the output circuit stage 500b to produce the frontend differential output signals 543. A folded cascode circuit is an extension of a cascode circuit and can include two or more cascode stages connected in a folded arrangement. Each cascode stage includes a series combination of transistors, usually composed of a lower transistor acting as an input device (common-emitter or common-source transistor) and an upper transistor acting as a cascode device (common-base or common-gate transistor). In a folded cascode arrangement, the output of the first cascode stage is folded back and connected to the input of the subsequent cascode stage. This creates a series connection of the cascaded cascode stages, enabling the reduction of the Miller effect and improving the bandwidth of the input receiver. In the arrangement shown in FIG. 5, the input transistor pair 532a-532b is the first cascode stage and the output signals 533a-533b of the first cascode stage are folded and connected to the input of the second cascode stage including cascode transistors 534a-534b.

In the example shown in FIG. 5, the input circuit stage 500a of analog frontend 500 has an input transistor pair 532a and 532b (collectively as input transistor pair 532). The input transistors 532a and 532b are configured to receive, at their gate terminals, analog differential input signals 531a (denoted as Vᵢₙₚ) and 531b (denoted as Vᵢₙₙ), respectively. The differential input signals 531a and 531b can be from external of the analog frontend 500, the input receiver (e.g., receiver 182), or the I/O circuit (e.g., I/O control circuit 112). For example, the analog differential input signals 531 may be received from a system controller (e.g., controller 115). The input transistor pair 532, in the example shown in FIG. 5, includes PMOS (p-type metal-oxide-semiconductor) transistors. The gate terminals of these PMOS transistors receive analog differential input signals 531. The source terminals of the input transistor pair 532 are coupled to the power supply (denoted by pn_Vcc) via a transistor 538 and a current source 542. In one embodiment, the current source 542 can also be implemented using a transistor (e.g., a PMOS transistor). The drain terminals of the input transistor pair 532 are folded and connected to the source terminals of the cascode transistors 534 in output circuit stage 500b. It is understood that the input transistor pair 532 can also be NMOS transistors or other types of transistors, with the corresponding configuration change of the cascode transistors. The use of PMOS or NMOS transistors of the input transistor pair 532 depends on the common mode voltage of the differential input signals 531 and possibly other factors. For example, PMOS transistors may be used when the common mode voltage of the differential input signals 531 may have a range close to the ground voltage (denoted by Vsslcl in FIG. 5), while NMOS transistors may be used when the common mode voltage of the differential input signals 531 may have a range close to the power supply voltage (denoted by pn_Vcc in FIG. 5).

The differential internal signals 533a (denoted as Vₒᵤₜₙ₁) and 533b (denoted as Vₒᵤₜₚ₁) from the input transistor pair 532 are folded and connected to the source terminals of cascode transistors 534a and 534b, respectively; and connected to the current sources 536a and 536b, respectively. If the current sources 536a and 536b are implemented using NMOS transistors, the differential internal signals 533a and 533b are then connected to the drain terminals of the current source transistors 536a and 536b, respectively. Cascode transistors 534a and 534b have a common gate terminal, which is biased at a voltage denoted by V_{bcascn}. The drain terminals of cascode transistors 534 provide the differential output signals 543a and 543b of the analog frontend 500, and are coupled to the power supply denoted by pn_Vcc via biasing transistors 544 and 548 and current sources 546 and 552, as shown in FIG. 5. Current sources 546 and 552 can also be implemented using transistors like PMOS transistors. Source terminals of cascode transistors 534a and 534b are coupled to the drain terminals of the current source transistors 536a and 536b, respectively, which in turn are coupled to electrical ground denoted by V_{sslcl}. In one example, when the current sources 536a and 536b are implemented using transistors, they have a common gate terminal (not shown in FIG. 5), which can be provided with a biasing voltage from a biasing circuit (not shown in FIG. 5). The biasing voltage of the current sources 536a and 536b can set the operating points of the cascode transistors 534 and provides a current to the cascode transistors 534.

The cascode transistors 534 can be particularly sized and biased such that the ratio of the gains of the input transistor pair 532 and cascode transistors 534 is configured to reduce or minimize the Miller effect. Cascode transistors 534, together with biasing/current sourcing/cascoding transistors 536, 544, 546, 548, and 552, can also be particularly sized and biased to provide the desired common mode of the frontend differential output signals 543 (including signals 543a and 543b). As described in more detail below, the biasing circuit 500c can be controlled to adjust the common mode voltages of the frontend differential output signals 543 such that the duty cycle of the signals 543 can be corrected or improved, if needed. In FIG. 5, for illustrative purposes, the biasing/current sourcing/cascode transistors 544, 546, 548, and 552 may be implemented using PMOS transistors and the current source transistors 536a and 536b may be implemented using NMOS transistors. It is understood that NMOS/PMOS or other transistors may be used, depending on the overall configuration of the folded cascode circuit of analog frontend 500 and the common mode requirements for the differential input signals 531 and differential output signals 543.

In FIG. 5, analog frontend 500, by using a folded cascode circuit configuration, generates the differential output signals 543, which may have a higher amplitude (or a higher signal range) and improved eye opening compared to the differential input signals 531. In other words, by using and particularly configuring the folded cascode circuit, analog frontend 500 can reduce or minimize the Miller effect to improve the bandwidth (by reducing the time constant). Analog frontend 500 can achieve a higher gain due to the folded cascode circuit, thereby providing a higher output signal amplitude and an improved eye opening. Analog frontend 500 can also be configured to have a wider input signal range by, for example, using PMOS as the input transistor pair and can thus operate with a low-voltage power supply (denoted by pn_Vcc), of e.g., 1.6V.

Moreover, in the biasing circuit 500c of analog frontend 500, one of the inputs may be a reference DC voltage (denoted by V_{refbias}) and the other input may be a time varying signal. This may introduce distortion if the tail current source is not an ideal current source. A cascode tail current source in input circuit stage 500a is used to reduce the distortion due to noise on the reference voltage (V_{refbias}). The cascode tail current source includes transistor 538 and current source 542, which may also be implemented using a transistor (e.g., a PMOS transistor). Biasing circuit 500c is used to generate the biases of cascode tail current source. With the cascode tail current source, the analog frontend 500 can tolerate reference voltage changes and therefore, making analog frontend 500 more robust.

Furthermore, the folded cascode configuration of analog frontend 500 uses only a single stage compared to a frontend having multiple stages of common source configurations. The latter configuration has a limited bandwidth, higher gate resistance of the input transistors, a high sensitivity to reference voltage changes, and a high likelihood of failure when operating under a low power supply voltage. In contrast, analog frontend 500 can avoid these limitations of a multiple stage common source configuration. Analog frontend 500 may further provide a high output impedance, which reduces the need of common mode feedback (CMFB). CMFB is used to regulate the common-mode voltage of a differential amplifier, a different transistor pair, or other differential circuitry. The common-mode voltage is the average voltage between the two input terminals of a differential amplifier or a differential transistor pair. CMFB is employed to ensure that the common-mode voltage remains within a specified range, providing better performance and stability in certain applications. As described above, the circuit configurations of analog frontend 500 have greater ability to tolerate common mode shifts and therefore reduces the need for CMFB. In some examples, the common mode voltage of the output signals 543 of analog frontend 500 shown in FIG. 5 can be set at the trip point of the subsequent inverter-based stage coupled to analog frontend 500, reducing the duty cycle distortion.

In some situations, the duty cycle distortion induced by analog frontend 500 needs to be further corrected or improved. As described above, using traditional DCC circuits such as those shown in FIG. 4 has many disadvantages like increased load at the output of the analog frontend, limited bandwidth, and higher power consumption. FIG. 5 illustrates a biasing circuit 500c that is controllable to adjust the common mode voltages of the frontend differential output signals 543a and 543b, such that duty cycle of the signals 543a and 543b are further corrected or improved. Biasing circuit 500c can be a part of, or integrated within, analog frontend 500.

As described above, biasing circuit 500c can be configured to provide biasing voltages and/or currents to the input circuit stage 500a and the output circuit stage 500b. Specifically, the gate terminals of biasing/current source transistors in the input circuit stage 500a and output circuit stage 500b may receive the biasing voltages/currents from biasing circuit 500c. Biasing circuit 500c, by controlling the biasing voltages/currents of the various transistors in the input circuit stage 500a and output circuit stage 500b of analog frontend 500, sets the operating points of analog frontend 500. For example, by providing predetermined biasing voltages/currents, the common mode voltages of differential output signals 543a and 543b can be particularly set or adjusted for enhancing the high-speed performance of analog frontend 500 (e.g., adjust the common mode voltage of the differential output signals 543 such the duty cycles of signals 543 are approximately 50%). Biasing circuit 500c is described in greater detail next.

With continued reference to FIG. 5, biasing circuit 500c, in some examples, includes several branches (two such branches are shown, but it is understood it may include additional branches). The first branch includes transistors 502 (e.g., a PMOS), 504 (e.g., a PMOS), 506 (e.g., an NMOS), and a variable resistive component 508. The variable resistive component 508 can be, for example, a variable resistor (denoted by R_{b}) or a transistor configured to function as a resistor. In this example, the source terminal of transistor 502 is coupled to a power supply (denoted by pn_vcc). The drain terminal of transistor 502 is coupled to the source terminal of transistor 504, and therefore the two transistors are connected in series. The gate terminal of transistor 502 is coupled to the drain terminal of transistor 504. The gate terminal of transistor 506 is coupled to an output of an operational amplifier 510 (op-amp 510). Op-amp 510 receives a reference voltage (denoted as V_{refbias}) at one input terminal 501a (e.g., the positive input terminal) of op-amp 510. Op-amp 510's other input terminal 501b (e.g., the negative input terminal) is coupled to the source terminal of transistor 506 and a first terminal of variable resistive component 508. The source terminal of transistor 506 and a first terminal of variable resistive component 508 are coupled together. The second terminal of variable resistive component 508 is coupled to electrical ground denoted by V_{sslcl}. Op-amp 510 can be configured to have a high input impedance and low output impedance, and have a high-gain. Op amp 510 is configured in a closed-loop configuration as shown in FIG. 5, such that the biasing current in the first branch of biasing circuit 500c is the reference voltage divided by resistance of variable resistive component 508 (i.e., V_{refbias}/R_{b}). The reference voltage V_{refbias} can be designed to have a value k*V_{cclo}, i.e., a fraction of the power supply voltage V_{cclo}. Therefore, the biasing current in the first branch of biasing circuit 500c can be calculated as k*V_{cclo}/R_{b}, wherein k is a positive number between 0 and 1, and R_{b} is a variable resistor controlled by a control signal (e.g., the duty cycle correction code denoted as DCC).

With continued reference to FIG. 5, the second branch of biasing circuit 500c is similarly configured as the first branch. For example, the second branch includes transistors 512 (e.g., a PMOS), 514 (e.g., a PMOS), 516 (an NMOS), and a variable resistive component 518. (denoted by R_{b}). The variable resistive component 518 can be, for example, a variable resistor (denoted by R_{b}) or a transistor configured to function as a resistor. In this example, the source terminal of transistor 512 is coupled to a power supply (denoted by pn_vcc). The drain terminal of transistor 512 is coupled to the source terminal of transistor 514. Furthermore, the drain terminal of transistor 514 and the gate terminal of transistor 512 are coupled together, forming a diode connection. The gate terminals of transistors 504 and 514 are coupled together so they have the same gate voltage. The gate voltage of the gate terminals of transistors 504 and 514 is denoted V_{bcascp}. The gate terminal of transistor 516 is coupled to the gate terminal of transistor 506 in the first branch and also coupled to the output of op-amp 510. The source terminal of transistor 516 is coupled to the first terminal of variable resistive component 518. The second terminal of variable resistive component 518 is coupled to electrical ground (denoted by V_{sslcl}). Variable resistive component 518 can be a variable resistor (denoted by R_{b}) or a transistor implement functioning as a variable resistor, The resistor (R_{b}) is a variable resistor controlled by a complimentary control signal (e.g., complimentary duty cycle correction code denoted by D̅C̅C̅).

By controlling the complimentary control signals (e.g., the duty cycle correction code denoted by DCC) and the complimentary duty cycle correction code denoted by D̅C̅C̅), the resistance of the variable resistive components 508 and 518 can be changed. In turn, the biasing currents generated in the first branch and second branch of biasing circuit 500c can be changed. Specifically, in the first branch, the gate terminal of biasing transistor 506 receives the output voltage of op-amp 510, and the source terminal of biasing transistor 506 is coupled to the negative input terminal of op-amp 510. Therefore, the biasing current in the first branch is set by the op-amp 510, biasing transistor 506, and the variable resistive component 508, as described above. When the resistance of variable resistive component 508 changes, the biasing current of the first branch changes too. Variable resistive component 508 may be implemented using resistors controlled by the duty cycle correction code (i.e., DCC code). For example, the variable resistive component 508 can include a plurality of resistors connected in series or in parallel. It can further include switches to connect resistors and/or disconnect other resistors, thereby changing the overall resistance of variable resistive component 508. The switches can be implemented by transistors (or other electrical switching components) controlled by the control signal (e.g., the DCC code).

Similarly, in the second branch of biasing circuit 500c, the biasing current in the second branch is set by the op-amp 510, biasing transistor 516, and the variable resistive component 518. As described above, the gate terminals of biasing transistor 516 is coupled to the gate terminal of biasing transistor 506. Therefore, the gate voltage (at node 511) is the same for both biasing transistor 506 and 516. When the resistance of variable resistive component 518 changes, the biasing current of the second branch changes too. Variable resistive component 518 may be implemented using resistors controlled by another duty cycle correction code. For example, the variable resistive component 518 can include a plurality of resistors connected in series or in parallel. It can further include switches to connect resistors and/or disconnect other resistors, thereby changing the overall resistance of variable resistive component 518. The switches can be implemented by transistors (or other electrical switching components) controlled by the complimentary control signal (e.g., complimentary duty cycle correction code denoted by D̅C̅C̅).

In one example, the control signals for variable resistive components 508 and 518 are complimentary to each other. Thus, when the control signals are implemented by the duty cycle correction code (DCC) and the complimentary duty cycle correction code (D̅C̅C̅), they are opposite to each other. For example, if the DCC code is 001, the D̅C̅C̅ code is 100; if the DCC code is 011, the D̅C̅C̅ code is 100, etc. Therefore, under the control of these two complimentary signals, variable resistive components 508 and 518 can change in the opposite directions. For example, if the variable resistive components 508 and 518 are a pair of variable resistors, the pair of variable resistors are controlled by the duty cycle correction code (DCC) and the complimentary duty cycle correction code (D̅C̅C̅), such that their respective resistances change in the opposite directions. That is, when the resistance of variable resistive component 508 increases, the resistance of variable resistive component 518 decreases, and vice versa. The amount of changes of resistances in variable resistive components 508 and 518 may be the same but in the opposite direction. Thus, if the resistance of variable resistive component 508 increases by 1 ohm, the resistance of variable resistive component 518 decreases by 1 ohm. When the resistances of variable resistive components 508 and 518 change, the biasing currents in the first and second branches of biasing circuits 500c also change. That is, the biasing currents passing through biasing transistors 506 and 516 also change. In addition, because the resistance of variable resistive components 508 and 518 can be controlled to change in the opposite directions with the same amount, the biasing currents passing through biasing transistors 506 and 516 may also change in the opposite directions by approximately the same amount. It is understood that the above-descriptions of the controlling of the variable resistive components to change the biasing currents in the first and second branches of biasing circuit 500c are illustrative. Alternative embodiments may be implemented. The change of biasing currents in the first and second branches of biasing circuit 500c may or may not the same, depending on the dimensions of biasing transistors 506 and 516, resistance changes of components 508 and 518 (e.g., variable resistors), and other factors.

With continued reference to FIG. 5, the first branch and the second branch of biasing circuit 500c can be configured to function as current generators configured to generate biasing currents/voltages for setting operating points of input circuit stage 500a and output circuit stage 500b. As described above, op-amp 510, biasing transistors 506 and 516, and variable resistive components 508 and 518 (e.g., variable resistors) operate together to generate the biasing currents in the first and second branches of biasing circuit 500c. Based on the biasing currents, the biasing voltages of PMOS transistors 502 and 504 can be set. As shown in FIG. 5, the biasing voltage of transistor 502 is denoted as biaspp, and the biasing voltage of transistor 512 is denoted as biaspn. These two bias voltages may be different from each other (i.e., biaspp≠biaspn), because the biasing currents in the first and second branches may be different (e.g., they are changed in opposite directions as described above).

The biasing currents in the first and second branches of biasing circuit 500c are mirrored to the two branches in the output circuit stage 500b. Specifically, transistors 502 and 504 form a current mirror (or a part of it). As shown in FIG. 5, the gate terminal of transistor 502 is coupled with the variable current source 546. As described above, transistor 502 and transistor 504 in the first branch form a diode connection. The variable current source 546 may include another transistor (e.g., a PMOS). The gate terminal of PMOS transistor of current source 546 may be coupled with the gate terminal of transistor 502, and therefore they have the same biasing voltage (denoted by biaspp). Therefore, using the first branch of biasing circuit 500c and the current source 546 including a transistor, the biasing current of the first branch of the biasing circuit 500c can be mirrored to the left branch of output circuit stage 500b, which provides the output signal 543b.

In a similar manner, the biasing current in the second branch of biasing circuit 500c is mirrored to the right branch of output circuit stage 500b, which provides the output signal 543a. Specifically, the gate terminal of transistor 512 is coupled with the variable current source 552. As described above, transistor 512 and transistor 514 in the second branch form a diode connection. The variable current source 552 may include another transistor (e.g., a PMOS). The gate terminal of PMOS transistor of current source 552 may be coupled with the gate terminal of transistor 512, and therefore they have the same biasing voltage (denoted by biaspn). Therefore, using the second branch of biasing circuit 500c and the current source 552 including a transistor, the biasing current of the second branch of the biasing circuit 500c can be mirrored to the right branch of output circuit stage 500b, which provides the output signal 543a.

As described above, the biasing currents in the first and second branches of biasing circuits 500c can be adjusted by controlling the resistances of the variable resistive components 508 and 518, respectively. As a result, when the biasing currents of the first and second branches of biasing circuit 500c are mirrored to the left and right branches of output circuit stage 500b, the net currents in the left and right branches of output circuit stage 500b are adjusted according to the resistances of the variable resistive components 508 and 518, respectively. In turn, when the net currents in the left and right branches of output circuit stage 500b are adjusted, the common mode voltages of the frontend differential output signals 543b and 543a are adjusted. Specifically, the net current in the left branch of the output circuit stage 500b is equal to the difference between the current flowing through the current source 546 (denoted by Iₚ) and the current flowing through the current source 536b (denoted by Iₙ). That is, the net current flowing in the left branch of output circuit stage 500b is equal to (Iₚ-Iₙ). As described above, the current flowing through the current source 546 (denoted by Iₚ) is mirrored from the first branch of the biasing circuit 500c and therefore may be varied by adjusting the resistance of the resistive component 508. The current flowing through the current source 536b (denoted by Iₙ) can be controlled by another branch (not shown) of biasing circuit 500c or another biasing circuit (not shown). The circuits that provide the biasing voltages for the current source 536b can be similar to the first or the second branches shown in FIG. 5, but without the variable resistive components 508 and 518. For example, they could use a fixed resistor to provide a fixed biasing voltage for current source 536b. As a result, the current flowing through the current source 536b (Iₙ) can be fixed too.

Similarly, the net current in the right branch of output circuit stage 500b is equal to the difference between the current flowing through the current source 552 (also denoted by Iₚ) and the current flowing through the current source 536a (also denoted by Iₙ). That is, the net current flowing in the right branch of output circuit stage 500b is equal to (Iₚ-Iₙ). While the current flowing in the right branch is similarly denoted by (Iₚ-Iₙ), it may or may not be the same as the net current flowing in the left branch. As described above, the biasing currents mirrored from the first and second branches of biasing circuit 500c are different, and therefore the biasing currents flowing through current sources 546 and 552 in the output circuit stage 500b are also different. The current flowing through the current source 536a (denoted by Iₙ) can be the same as the current flowing through the current source 536b (also denoted by Iₙ). As a result, the difference of the currents flowing through the left and right branches of output circuit stage 500b is controlled by the difference of the currents flowing through current sources 546 and 552, which in turn is controlled by the resistance difference between the variable resistive components 508 and 518.

The common mode voltages of output signals 543a and 543b are affected by the net currents flowing through the left and right branches of output circuit stage 500b, which are varied in the opposite directions. Thus, the common mode voltages of the output signals 543a and 543b are varied in opposite directions. For example, if the common mode voltage of output signal 543a increases, the common mode voltage of output signal 543b decreases. Ideally, the common mode voltage of output signals 543a and 543b should be approximately at the half point of the power supply voltage (e.g., at Vccq/2, where Vccq is the power supply voltage and can be the same as pn_vcc in FIG. 5).

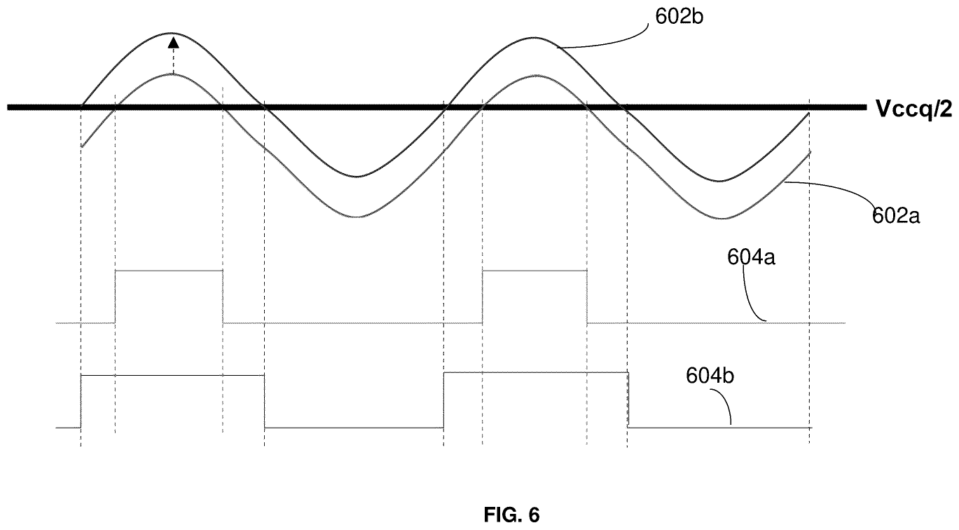

FIG. 6 illustrates a waveform 602a representing one of the frontend differential output signals 543a or 543b before duty cycle correction is performed. As shown in FIG. 6, the common mode voltage of the waveform 602a is below the ideal value of a half of the power supply voltage (i.e., Vccq/2). Correspondingly, for waveform 602a, the duty cycle is less than the preferred value of 50%. In other words, there may be duty cycle distortions that need to be corrected or improved. Waveform 604a illustrates a digitized waveform of waveform 602a showing that the duty cycle is less than 50% (i.e., anything above the threshold voltage of Vccq/2 is high and anything below the threshold voltage of Vccq/2 is low). As described above, duty cycle distortion may result in limited bandwidth and reduced eye openings. Using the circuits and technologies described herein, the common mode of the frontend differential output signals 543a or 543b can be adjusted. In FIG. 6, for example, after increasing the common mode voltage of one of the frontend differential output signals 543a or 543b, waveform 602a becomes waveform 602b, which represents one of the output signals 543a or 543b after duty cycle correction. As shown in FIG. 6, the duty cycle correction makes the common mode voltage of the waveform 604a to be approximately at the ideal value of a half of the power supply voltage (i.e., Vccq/2). Correspondingly, for waveform 602b, the duty cycle is approximately 50%. Waveform 604b is a digitized waveform of waveform 602b showing that the duty cycle is corrected to approximately 50%.

Accordingly, FIG. 6 illustrates that by varying the common mode voltage of the frontend differential output signals 543a and 543b, the duty cycles of the signals can be corrected or improved to their preferred values (e.g., 50%). As described above, differential signals are signals with opposite polarities. Therefore, if a common mode voltage of the differential output signal 543a is less than the preferred value, the common mode voltage of the differential output signal 543b may be greater than the preferred value, and vice versa. In turn, the duty cycle of differential output signal 543a may be below the preferred value (e.g., 50%), and the duty cycle of differential output signal 543b may be greater than the preferred value (e.g., 50%), and vice versa. Thus, according to the techniques described above, the common mode voltages of the two differential signals are changed in opposite directions (e.g., increasing the common mode voltage of output signal 543a while decreasing the common mode voltage of output signal 543b, and vice versa). The duty cycles corrections for the differential output signals are also in the opposite directions.

With reference back to FIG. 5, the output circuit stage 500b of analog frontend 500 is coupled to an inverter-based stage to receive the frontend differential output signals 543a and 543b. The inverter-based stage comprises a pair of inverters, each of which has a feedback resistor (denoted by R_{fb}). As described above, the feedback resistor connects the input and the output of the inverter, forming a feedback path. The common mode voltage of each of the output signals 543a and 543b is affected by the ratio of the resistance of the feedback resistor (denoted by R_{fb}) and the resistance of the variable resistive component 508 and 518) (denoted by R_{b}), as shown in the below equations.

$${V}_{outcm} ∝ ( {I}_{p} - {I}_{n} ) {R}_{fb} \qquad [ 1 ]$$

$${V}_{outcm} ∝ \frac{{V}_{cclo}}{{R}_{b}} {R}_{fb} \qquad [ 2 ]$$

In the above equations, V_{outcm} denotes the common mode voltage of the output signal 543 (either 543a or 543b), Iₚ denotes the current flowing through the current source 546 or 552 (i.e., PMOS-based current source), Iₙ denotes the current flowing through the current source 536a or 536b (i.e., NMOS-based current source), R_{fb} denotes the feedback resistor in an inverter-based stage that receives the output signals 543, and R_{b} denotes the variable resistive component (e.g., component 508 or 518) used in the biasing circuit 500c.

As seen from the above equations, the common mode voltage of the output signal 543 is a proportional to the ratio of the resistance of the feedback resistor (denoted by R_{fb}) and the resistance of the variable resistive component 508 and 518 (denoted by R_{b}). Therefore, the common mode voltage is insensitive to variation of the resistance of variable resistive component 508 and 518 alone, or variation of the resistance of the feedback resistor (denoted by R_{fb}) alone. The resistance of any of the resistors alone may be affected by many factors like the chip manufacturing process, the operating temperature, voltage, etc. However, because the common mode voltage is a ratio of two resistors (R_{fb} and R_{b}), it is thus independent of any single resistor variation. This way, the common mode voltage adjustment is more robust and less sensitive to process and temperature variations.

FIG. 5 further illustrates that the output circuit stage 500b may include other transistors like the transistors 544 and 548, which can be PMOS transistors. As shown in FIG. 5, transistors 544 and 548 can also be cascode transistors. As described above, the transistors 504 and 514 in the biasing circuit 500c can be coupled together to provide a biasing voltage (denoted as V_{bcascp}) for transistors 544 and 548 in the output circuit stage 500b. Thus, the gate terminals of transistors 544 and 548 are coupled to the gate terminals of transistors 504 and 514. The transistors having gate terminals coupled together may be matches in size and therefore, the biasing voltages are provided to the PMOS cascode transistors 544 and 548 of output circuit stage 500b from biasing circuit 500c for setting the particular operation points. In the example shown in FIG. 5, the biasing voltage V_{bcascp} is further provided to transistor 538 in the input circuit stage 500a, which is a part of the cascode tail current source including transistors 538 and 542.

In FIG. 5, NMOS cascode transistors 534a and 534b are coupled together by their gate terminals, which receive a biasing voltage V_{bcascn}. This biasing voltage can be generated using another branch of biasing circuit 500c (not shown) or another biasing circuit (not shown). It is understood that the circuit for generating biasing voltage V_{bcascn} can be similar to those shown in FIG. 5 (e.g., using NMOS based current mirrors) or with some known variations (e.g., replacing PMOS transistors with NMOS transistors, changing the size of the transistors, etc.), and therefore are not described.

The configuration shown in FIG. 5 has a biasing circuit 500c that is configured such that the common mode of the folded cascode circuit of analog frontend 500 is biased based on termination with respect to ground. Termination in high-speed signal communication refers to the use of electrical components (e.g., resistors, capacitors, and/or inductors) to particularly terminate transmission lines and minimize signal reflections. The termination can be configured to terminate with respect to electrical ground or the power supply. If the termination is configured to be with respect to the electrical ground, the circuit needs to be biased at an operation point (e.g., a common mode voltage) that is close to the ground. For example, the termination may require that the operation point to be approximately ⅙ of the power supply voltage. In some examples, the operation point may be set at approximately ½ of the power supply voltage. The folded cascode circuit described above can be configured to have common mode voltage biased close to the ground voltage (e.g., 0V or ⅙ of the power supply voltage). Therefore, the biasing circuit 500c can be configured accordingly. As described above, in biasing circuit 500c, the resistive components 508 and 518 are tunable resistors such that their resistances can be changed. As a result, the biasing currents can be changed, and biasing voltages can be changed too. Biasing circuit 500c can therefore be tunable, not only for setting the common mode voltages of differential output signals 543 for duty cycle correction, but also for adapting to different termination schemes and/or other requirements of analog frontend 500.

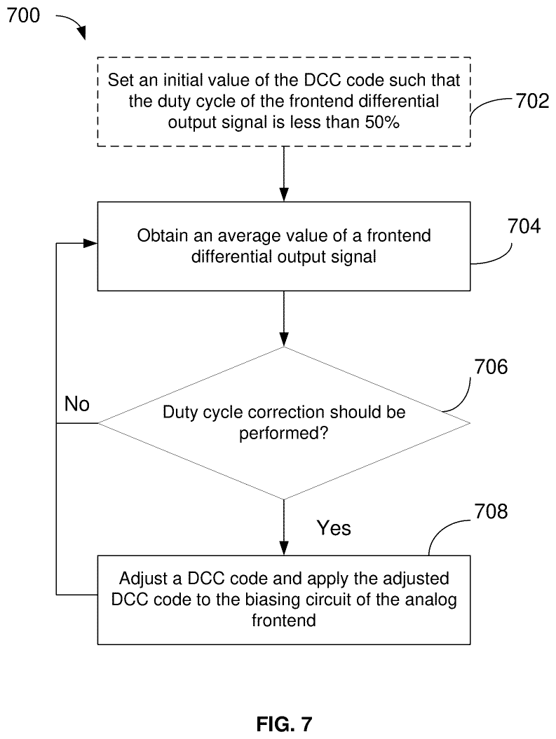

FIG. 7 illustrates flowcharts showing a method or methods that support techniques for correcting duty cycle in accordance with examples as disclosed herein. Method 700 may be performed by, for example, a memory controller (e.g., local controller 135 and/or system controller 115), which may be implemented using apparatus 300. Method 700 is performed for duty cycle correction for an input receiver (e.g., input receiver 182) of an input/output (I/O) circuit operable to communicate data in a multi-giga Hertz frequency range. The input receiver comprises an analog frontend (e.g., analog frontend 500) with a biasing circuit (e.g., biasing circuit 500c).

In one example, method 700 includes a block 702, which sets an initial duty cycle correction (DCC) code to a value sufficiently small such that the duty cycle of the frontend differential output signal is less than the preferred value (e.g., 50%). For example, when the memory device (e.g., device 130) initializes, the initial DCC code can be set to an initial value (e.g., a small value) such that the initial duty cycle is sufficiently less than the preferred value (e.g., much less than 50%). As a result, the subsequent duty cycle correction only increases the duty cycle of the output signals to the preferred value (e.g., 50%). It can be also set to be large enough so that the subsequent duty cycle correction only decreases the duty cycle of the output signals to the preferred value (e.g., 50%). Block 702 is an option block and is not necessary for performing the duty cycle correction. In other words, the technologies and circuits described herein can perform duty cycle correction irrespective of the initial value of the duty cycle.

Block 704 of method 700 obtains an average value of a frontend differential output signal. The average value of the differential output signal represents the common mode voltage. Block 706 determines, based on the average value of the frontend differential output signal, if duty cycle correction is to be performed. For example, if the average value of the frontend differential output signal is greater than or equal to a half of a power supply voltage (e.g., Vccq/2) of the analog frontend, it is determined that the duty cycle correction needs not be performed, and the method 700 loops back to block 704 to keep monitoring the average value of the differential output signals.

If the average value of the frontend differential output signal is less than a threshold value (e.g., a half of a power supply voltage, i.e., Vccq/2) of the analog frontend, it is determined that the duty cycle correction should be performed and method 700 proceeds to the next block 708. Block 708 adjusts a DCC code (and correspondingly the complimentary D̅C̅C̅ code) and provides the adjusted DCC code to the biasing circuit (e.g., circuit 500c) of the analog frontend. The adjusted DCC code causes adjusting of a common mode voltage of the frontend differential output signal (e.g., signal 543) such that a duty cycle of the frontend differential output signal, or a digital representation thereof, is varied. For example, in this example, because the average value of the output signal (and thus the duty cycle) is less than the preferred value (e.g., 50%), the DCC code is adjusted to increase the duty cycle of the frontend differential output signal (e.g., increase until the duty cycle is approximately 50%).

Some of the blocks (e.g., blocks 704, 706, and 708) of the above process can be repeated so that the duty cycle of the differential output signal is adjusted dynamically.

It should be noted that the described techniques include possible implementations, and that the operations and the blocks may be rearranged, reordered, or otherwise modified and that other implementations are possible. For example, instead of applying a DCC code to increase the duty cycle, a DCC code can be applied to decrease the duty cycle of a frontend differential output signal. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An input receiver of an input/output (I/O) circuit operable to communicate data, the input receiver comprising:
an analog frontend operable in a multi-giga Hertz frequency range, the analog frontend comprises:
an input circuit stage configured to receive analog differential input signals from external of the I/O circuit;
an output circuit stage configured to provide frontend differential output signals based on the received analog differential input signals; and
a biasing circuit controllable to adjust common mode voltages of the frontend differential output signals such that duty cycles of the frontend differential output signals are varied.

2. The input receiver of claim 1, wherein the analog frontend comprises a cascode circuit comprising:
an input transistor pair configured to receive the analog differential input signals;
cascode transistors coupled to the input transistor pair, the cascode transistors are configured to reduce input capacitance of the input transistor pair caused by the Miller capacitance effect; and
a first current source coupled to the input transistor pair, the first current source being biased to provide approximately fixed currents to the cascode transistors.

3. The input receiver of claim 2, wherein the cascode transistors form a folded cascode circuit.

4. The input receiver of claim 1, wherein the biasing circuit comprises:
a plurality of variable resistive components configured to generate a plurality of biasing currents; and
a plurality of current mirrors coupled to the plurality of variable resistive components to receive the plurality of biasing currents, the plurality of current mirrors configured to provide biasing voltages for mirroring the plurality of biasing currents to the output circuit stage of the analog frontend.

5. The input receiver of claim 4, wherein the plurality of variable resistive components comprises a pair of variable resistors configured to receive complimentary control signals, wherein the pair of variable resistors are controllable to vary their respective resistances in opposite directions based on the complimentary control signals.

6. The input receiver of claim 5, wherein the complimentary control signals are based on duty cycle correction (DCC) codes that are complimentary to each other.

7. The input receiver of claim 4, wherein the output circuit stage of the analog frontend comprises:
a second current source configured to receive the biasing voltages from the plurality of current mirrors, and generate mirrored biasing currents of the plurality of biasing currents, wherein the mirrored biasing currents are variable biasing currents controlled based on the plurality of variable resistive components.

8. The input receiver of claim 7, wherein the second current source comprises two current source transistors configured to vary the mirrored biasing currents based on respective biasing voltages, wherein the mirrored biasing currents are varied in opposite directions such that the common mode voltages of the frontend differential output signals are varied in opposite directions based on the mirrored biasing currents.

9. The input receiver of claim 4, wherein the output circuit stage further comprises cascode transistors coupled to the input circuit stage, the cascode transistors being configured to provide the frontend differential output signals.

10. The input receiver of claim 4, wherein the biasing circuit further comprises:
an operational amplifier configured to receive a reference bias voltage, wherein an input of the operational amplifier is coupled to one of the plurality of variable resistive components, and an output of the operational amplifier is coupled to a plurality of biasing transistors coupled to the variable resistive components.

11. The input receiver of claim 1, further comprising an inverter-based stage coupled to the analog frontend to receive the frontend differential output signals, the inverter-based stage comprises a pair of inverters.

12. The input receiver of claim 11, wherein the inverter-based stage further comprises a pair of resistors, each being coupled to an input and an output of an inverter of the pair of inverters to form a feedback path associated with the inverter.

13. A memory device comprising:
an input/output (I/O) circuit having an input receiver, the input receiver comprising:
an analog frontend operable in a multi-giga Hertz frequency range, the analog frontend comprises:
an input circuit stage configured to receive analog differential input signals from external of the I/O circuit;
an output circuit stage configured to provide frontend differential output signals based on the received analog differential input signals;
a biasing circuit controllable to adjust common mode voltages of the frontend differential output signals such that duty cycles of the frontend differential output signals are varied;
an array of memory cells coupled to the I/O circuit to receive and transmit data; and
a memory controller configured to control the array of memory cells and the I/O circuit.

14. A system comprising:
a processor; and
a memory device coupled to the processor, wherein the memory device comprises:
an input/output (I/O) circuit having an input receiver, the input receiver comprising an analog frontend operable in a multi-giga Hertz frequency range, the analog frontend comprising:
an input circuit stage configured to receive analog differential input signals from external of the I/O circuit;
an output circuit stage configured to provide frontend differential output signals based on the received analog differential input signals;
a biasing circuit controllable to adjust common mode voltages of the frontend differential output signals such that duty cycles of the frontend differential output signals are varied;
an array of memory cells coupled to the I/O circuit to receive and transmit data; and
a memory controller configured to control the array of memory cells and the I/O circuit.

15. A method of performing duty cycle correction for an input receiver of an input/output (I/O) circuit operable to communicate data in a multi-giga Hertz frequency range, the input receiver comprising an analog frontend with a biasing circuit, the method comprising:
obtaining an average value of a frontend differential output signal;
determining if a duty cycle correction is to be performed based on the average value of the frontend differential output signal; and
in accordance with a determination that the duty cycle correction (DCC) is to be performed,
adjusting a DCC code and applying the adjusted DCC code to the biasing circuit of the analog frontend, wherein the adjusted DCC code causes adjusting of a common mode voltage of the frontend differential output signal such that a duty cycle of the frontend differential output signal, or a digital representation thereof, is varied.

16. The method of claim 15, wherein determining if the duty cycle correction is to be performed based on the average value of the frontend differential output signal comprises:
determining if the average value of the frontend differential output signal is greater than or equal to a threshold value.

17. The method of claim 15, further comprising, prior to obtaining the average value of the frontend differential output signal, setting an initial value of the DCC code such that the duty cycle of the frontend differential output signal is less than 50%.

18. The method of claim 15, wherein adjusting the DCC code comprises adjusting the DCC code to increase the duty cycle of the frontend differential output signal.

19. The method of claim 15, further comprising repeating one or more actions performed in claim 15 to adjust the duty cycle of the frontend differential output signal to approximately 50%.
